(19) United States
(12) Patent Application Publication
(10) Pub. No.: US 2021/0234117 A1
(43) Pub. Date: Jul. 29, 2021

(54) DISPLAY PANEL AND METHOD OF MANUFACTURING THEREOF

(71) Applicant: Shenzhen China Star Optoelectronics Semiconductor Display Technology Co., Ltd., Shenzhen (CN)

(72) Inventor: Xiaoming LIANG, Shenzhen (CN)

(73) Assignee: Shenzhen China Star Optoelectronics Semiconductor Display Technology Co., Ltd., Shenzhen (CN)

(21) Appl. No.: 16/625,710

(22) PCT Filed: Nov. 15, 2019
(86) PCT No.: PCT/CN2019/118951

§ 371 Date: Dec. 22, 2019

(30) Foreign Application Priority Data
Nov. 1, 2019 (CN) 201911057778.5

(51) Int. Cl. H01L 51/52; H01L 27/32; H01L 51/56

(52) U.S. Cl. CPC H01L 51/5228; H01L 27/3246; H01L 27/3258; H01L 2227/323; H01L 51/56

(57) ABSTRACT

A display panel and a method of manufacturing thereof are provided. The display panel includes an insulating layer, a passivation layer, an auxiliary cathode, a planarization layer, a pixel defining layer, a via hole, and a conductive layer. The method of manufacturing the display panel includes steps of forming an insulating layer, forming an auxiliary cathode, forming a passivation layer, forming a planarization layer, forming a pixel defining layer, defining a via hole, and forming a conductive layer.

### BACKGROUND OF INVENTION

### Field of Invention

The present invention relates to the field of display technology, and more particularly, to a display panel and a method of manufacturing thereof.

### Description of Prior Art

Organic light emitting diode (OLED) devices have attracted much attention and development due to their flexibility, fast response times, wide color gamut, and low energy consumption. The OLED devices are composed of one or more layers of organic materials that are disposed between an anode, a cathode, and an electrode. At a certain voltage, holes and electrons are injected from the anode and the cathode, respectively, into the organic light emitting layer to form excitons, and the excitons are in radiative transition to emit light. An active-matrix organic light-emitting diode (AMOLED) display can be classified into a bottom-emitting display and a top-emitting display according to light emitted from the direction of the array substrate or from the direction of the cover plate. The top-emitting display needs to transmit light through a cathode, so the cathode must have a certain transmittance.

Currently, cathode materials for top-emitting displays are magnesium-silver alloys, transparent oxides, etc. In order to ensure the cathode have a good transmittance, thickness of the cathode is made thinner, which results in a larger sheet resistance of the cathode. Therefore, in large-sized OLED display devices, voltage drop (IR Drop) occurrs in a light emitting region away from the cathode power input, which results in a device having a lower luminance than a light emitting region close to the cathode power input. Luminance uniformity in the entire display devices occurrs.

In order to solve the problem of voltage drop of large-sized display devices, the conventional display panel directly forms an auxiliary cathode 100 on the array substrate as shown in FIG. 1, and the auxiliary cathode 100 is connected to the cathode layer 300 of the display panel to reduce the sheet resistance of the cathode layer 300. However, in the manufacturing process of large-sized OLED devices, various layers of OLEDs are formed by adopting an open evaporation mask during vapor depositing. Because the layers are formed in order, the position reserved for the cathode and the auxiliary cathode to be overlapped is covered by the organic film 200, the auxiliary cathode 100 and the cathode layer 300 cannot be directly connected. And a function of the auxiliary cathode 100 fails.

### SUMMARY OF INVENTION

The object of the present invention is to solve the technical problem that the cathode and the auxiliary cathode are blocked by the organic material in the conventional display panel, so that the auxiliary cathode and the cathode cannot be connected, resulting in failure of the auxiliary cathode.

Another object of the present invention is to solve the technical problem that the display devices have a voltage drop and an uneven brightness on the display devices.

A display panel includes: an insulating layer; a passivation layer, and the passivation layer is disposed on a side surface of the insulating layer, and an auxiliary cathode is disposed in the passivation layer and attached to a surface of the insulating layer; a planarization layer disposed on a side surface of the passivation layer away from the insulating layer; a pixel defining layer disposed on a side surface of the planarization layer away from the passivation layer; a via hole sequentially penetrating the pixel defining layer, the planarization layer, and the passivation layer, and the via hole is defined opposite to the auxiliary cathode; and a conductive layer, and the conductive layer is disposed in the via hole and connected to the auxiliary cathode.

In one embodiment, the display panel further includes an organic layer disposed on a side surface of the pixel defining layer away from the planarization layer; and a cathode layer disposed on a side surface of the conductive layer and the organic layer away from the pixel defining layer.

In one embodiment, a thickness of the conductive layer is less than a depth of the via hole.

In one embodiment, the conductor layer is made of nano silver.

In one embodiment, the cathode layer is electrically connected to the conductive layer, and the conductive layer is electrically connected to the auxiliary cathode.

In one embodiment, the display panel further includes: a substrate; a buffer layer disposed on a side surface of the substrate; an active layer disposed on a side surface of the buffer layer away from the substrate; a gate insulating layer disposed on a side surface of the active layer away from the buffer layer; a gate layer disposed on the side surface of the gate insulating layer away from the active layer; and a source/drain layer disposed on the side surface of the insulating layer away from the buffer layer, wherein the source/drain layer is passed through the insulating layer and electrically connected to the active layer.

A method of manufacturing a display panel includes following steps of: forming an insulating layer, and the insulating layer is formed on an upper surface of a substrate; forming an auxiliary cathode, and the auxiliary cathode is formed on an upper surface of the insulating layer; forming a passivation layer, and the passivation layer is formed on the upper surface of the insulating layer and an upper surface of the auxiliary cathode; forming a planarization layer, and the planarization layer is formed on an upper surface of the passivation layer; forming a pixel defining layer, and the pixel defining layer is formed on an upper surface of the planarization layer; defining a via hole, and the via hole is sequentially penetrating the pixel defining layer, the planarization layer, and the passivation layer; and the pixel defining layer, the planarization layer, and the passivation layer are disposed above the auxiliary cathode; and forming a conductive layer, and the conductive layer is formed in the via hole.

In one embodiment, a step of the forming the conductive layer includes following steps of: forming an organic layer, and the organic layer is formed on an upper surface of the pixel defining layer, and a second organic layer is formed on an inner sidewall of the via hole and a bottom thereof; preparing a first reaction solution, and an organic solvent is added to the via hole, and the second organic layer is dissolved to form the first reaction solution; preparing a second reaction solution, and a nano silver solution is added to the via hole, and the nano silver solution is mixed with the first reaction solution to form the second reaction solution; and forming the conductive layer, and the second reaction solution is processed to form the conductive layer.

In one embodiment, after a step of forming the conductive layer, and the step of forming the conductive layer further includes following steps: forming the cathode layer, and the cathode layer is formed on an upper surface of the organic layer and an upper surface of the conductive layer.

In one embodiment, a step of the forming the conductive layer includes following steps: vacuum baking the second reaction solution; and volatilizing the organic solvent to precipitate nano silver.

The technical effect of the display panel according to the embodiments of the present invention is that a conductive layer is formed in the via hole above the auxiliary cathode, and the conductive layer has a good conductivity, so that the cathode layer can be effectively overlapped to the auxiliary cathode and reduce the sheet resistance of the cathode layer. The voltage drop of the display panel is improved, and the luminance uniformity in the display panel is further improved.

### BRIEF DESCRIPTION OF DRAWINGS

FIG. 1 is a schematic view of a display panel in the prior art.

FIG. 2 is a schematic view of a display panel according to an embodiment of the present invention.

FIG. 3 is a flowchart of a method of manufacturing the display panel according to one embodiment of the present invention.

FIG. 4 is a schematic view of a display panel after defining a via hole according to one embodiment of the present invention.

FIG. 5 is a flowchart of manufacturing a conductive layer according to one embodiment of the present invention.

FIG. 6 is a schematic view of a display panel after forming an organic layer according to one embodiment of the present invention.

FIG. 7 is a schematic view of a display panel after preparing a first reaction solution according to one embodiment of the present invention.

FIG. 8 is a schematic view of a display panel after preparing a second reaction solution according to one embodiment of the present invention.

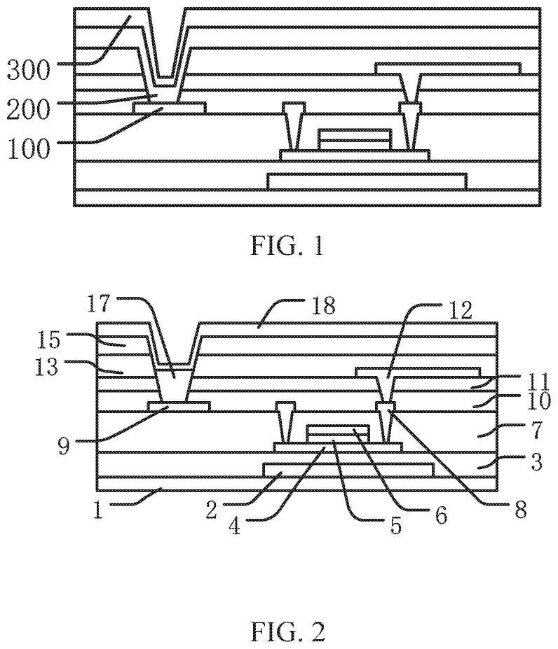

### REFERENCE NUMERALS

auxiliary cathode 100; organic film 200; cathode layer 300; substrate 1; light shielding layer 2; buffer layer 3; active layer 4; gate insulating layer 5; gate layer 6; insulating layer 7; source/drain layer 8; auxiliary cathode 9; passivation layer 10; planarization layer 11; electrode layer 12; pixel defining layer 13; via hole 14; organic layer 15; second organic layer 151; first reaction solution 16; conductive layer 17; and cathode layer 18.

### DETAILED DESCRIPTION OF PREFERRED EMBODIMENTS

The preferred embodiments of the present invention are described in detail below with reference to the accompanying drawings. Those skilled persons in the art will easily understand how to implement the invention. The invention can be implemented by the embodiments, so that the technical content of the disclosure will be clear, so that those skilled persons in the art will understand how to implement the invention. The present invention may be accomplished in many different embodiments, and the scope of the invention is not limited to the embodiments described herein.

Directional terms mentioned in this application, such as “up,” “down,” “forward,” “backward,” “left,” “right,” “inside,” “outside,” “side,” etc., are merely indicated the direction of the drawings. Therefore, the directional terms are used for illustrating and understanding of the application rather than limiting thereof.

In the drawings, identical components are marked with the same reference numerals, and structural or components having similar functions are marked with similar reference numerals. Moreover, the size and thickness of each component shown in the drawings are arbitrarily shown for understanding and describing, and the invention does not limit the size and thickness of each component.

When a component is described as “on” another component, the component can be disposed directly on the other component. Also, one component is disposed on an intermediate component, and the intermediate component is disposed on another component. When a component is described as “installed” or “connected” to another component, it can be understood as directly “installed” or “connected” to another component.

Referring to FIG. 2, a display panel including a substrate 1, a light shielding layer 2, a buffer layer 3, an active layer 4, a gate insulating layer 5, a gate layer 6, an insulating layer 7, a source/drain layer 8, an auxiliary cathode 9, a passivation layer 10, a planarization layer 11, an electrode layer 12, a pixel defining layer 13, an organic layer 15, conductor layer 17, and cathode layer 18.

The substrate 1 is a glass substrate, which has a support function and is used as a substrate.

The light shielding layer 2 is disposed on an upper surface of the substrate 1 to block light. The light shielding layer 2 is made of a light shielding material, and the light shielding material is a metal, which includes molybdenum (Mo), aluminum (Al), copper (Cu), titanium (Ti), or an alloy.

The buffer layer 3 is disposed on an upper surface of light shielding layer 2 and an upper surface of substrate 1. The buffer layer 3 has a buffer function. The buffer layer 3 made of an inorganic material. The inorganic material includes a silicon oxide, a silicon nitride, or a multilayer structure made of silicon oxide and silicon nitride.

The active layer 4 is disposed on an upper surface of the buffer layer 3, and the active layer 4 is made of a semiconductor material, and the semiconductor material includes indium gallium zinc oxide (IGZO), indium gallium titanium oxide (IZTO), and indium gallium zinc titanium oxide (IGZTO). The active layer 4 is disposed above the light shielding layer 2, that is, the active layer 4 is disposed opposite to the light shielding layer 2, and the active layer 4 provides circuit support for the display panel.

The gate insulating layer 5 is disposed on an upper surface of the active layer 4, and the gate insulating layer 5 is made of an inorganic material, and the inorganic material includes a silicon oxide, a silicon nitride, or a multilayer structure made of silicon oxide and silicon nitride. The gate insulating layer 5 is disposed opposite to the active layer 4, and the gate insulating layer 5 functions as an insulator to prevent short circuits between traces in the display panel.

The gate layer 6 is disposed on an upper surface of the gate insulating layer 5, and the gate layer 6 is made of a metal material, and the metal material includes molybdenum (Mo), aluminum (Al), copper (Cu), titanium (Ti), an alloy thereof, or a multilayer film structure. The gate layer 6 is disposed opposite to the gate insulating layer 5.

The insulating layer 7 is disposed on the upper surfaces of the gate layer 6, the active layer 4, and the buffer layer 3. The insulating layer 7 is made of an inorganic material, and the inorganic material includes silicon oxide, silicon nitride, or a multilayer film structure. The insulating layer 7 acts as an insulator to prevent short circuits. A via hole of the insulating layer is defined above the active layer 4, and the via hole of the insulating layer penetrates through the insulating layer 7, and the via hole of the insulating layer facilitates electrical connection between the electrode layer 12 and the active layer 4.

The source/drain layer 8 is disposed on an upper surface of the insulating layer 7. The source/drain layer 8 is made of a metal material, and the metal material includes molybdenum (Mo), aluminum (Al), copper (Cu), titanium (Ti), an alloy thereof, or a multilayer film structure. A part of the metal material is disposed in the via hole of the insulating layer, and the source/drain layer 8 is electrically connected to the active layer 4 through the via hole of the insulating layer to form an electrical connection.

The auxiliary cathode 9 is disposed on the upper surface of the insulating layer 7, and the auxiliary cathode 9 is overlapped to the cathode so as to reduce the sheet resistance of the cathode.

The passivation layer 10 is disposed on the upper surfaces of the insulating layer 7, the source/drain layer 8, and the auxiliary cathode 9. The material of the passivation layer 10 includes a silicon oxide material. The passivation layer 10 has a blocking function and blocks the external moisture.

The planarization layer 11 is disposed on an upper surface of the passivation layer 10. The planarization layer 11 makes the surface of the film layer to be smooth, which facilitates the subsequent attaching of the film layer and avoids detachment. A via hole of planarization layer is defined in the planarization layer 11, and the via hole of planarization layer is disposed opposite to the source/drain layer 8 so as to provide a channel for the electrode layer 12.

The electrode layer 12 is disposed on an upper surface of the planarization layer 11. The electrode layer 12 is a pixel electrode. The electrode layer 12 is made of an indium tin oxide material and is filled in the via hole of the planarization layer, so that the electrode layer 12 and the source/drain layers 8 are electrically connected, which provides circuit support for the illumination of the subsequent luminescent material.

The pixel defining layer 13 is disposed on the upper surfaces of the planarization layer 11 and the electrode layer 12, and functions to define the size of the light emitting layer of the display panel.

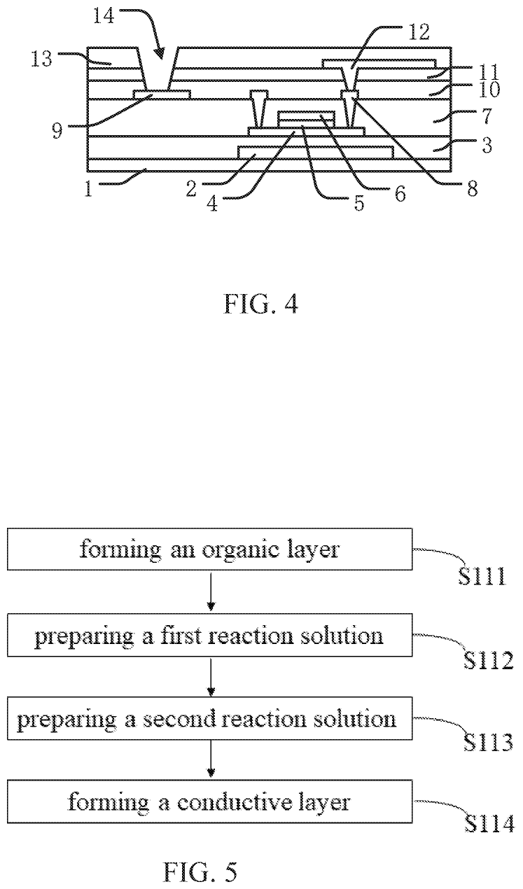

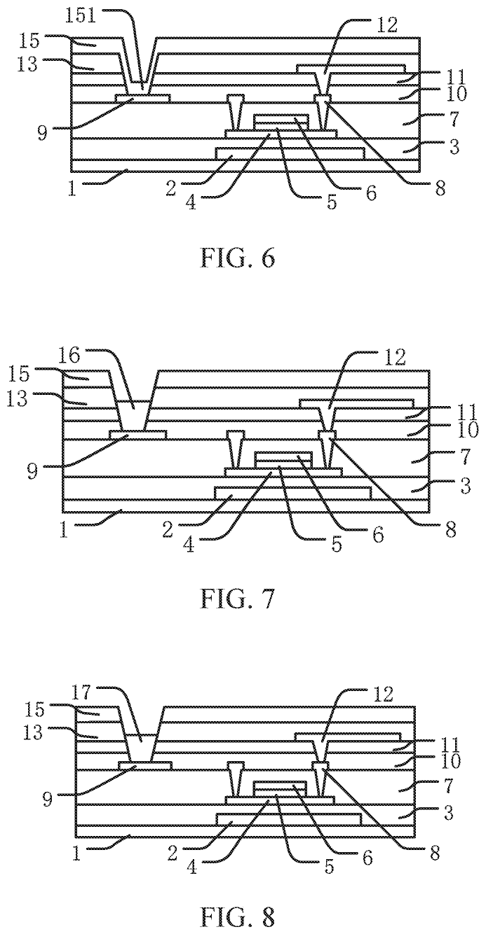

The via hole 14 as shown in FIG. 4 sequentially penetrates through the pixel defining layer 13, the planarization layer 11, and the passivation layer 10. The via hole 14 is disposed opposite to the auxiliary cathode 9 so as to provide a channel for the conductive layer 17 and the cathode layer 18.

The organic layer 15 is disposed on an upper surface of the pixel defining layer 13, the organic layer 15 is made of an organic material, and the organic layer 15 is a multilayer film structure made of organic film layers. The organic layer 15 includes a hole injection layer, a hole transport layer, an electron injection layer, an electron transport layer, etc.

The conductive layer 17 is disposed in the via hole 14 and is connected to the auxiliary cathode 9. The conductive layer 17 is made of nano silver and has good electrical conductivity. The thickness of the conductive layer 17 is less than the depth of the via hole 14, and the conductive layer 17 serves as connection between the auxiliary cathode 9 and the cathode layer 18, so that the cathode layer 18 can be effectively overlapped to the auxiliary cathode 9, reducing the voltage drop of the display panel to further improve display uniformity of the display panel.

The cathode layer 18 is disposed on the upper surface of the organic layer 15 and the conductive layer 17, and the cathode layer 18 is effectively overlapped to the auxiliary cathode 9 through the conductive layer 17, thereby reducing the voltage drop of the display panel and further improving display uniformity of the display panel.

The technical effect of the display panel according to the embodiments of the present invention is that a conductive layer is formed in the via hole above the auxiliary cathode, and the conductive layer has a good conductivity, so that the cathode layer can be effectively overlapped to the auxiliary cathode and reduce the sheet resistance of the cathode layer. The voltage drop of the display panel is improved, and luminance uniformity in the display panel is further improved.

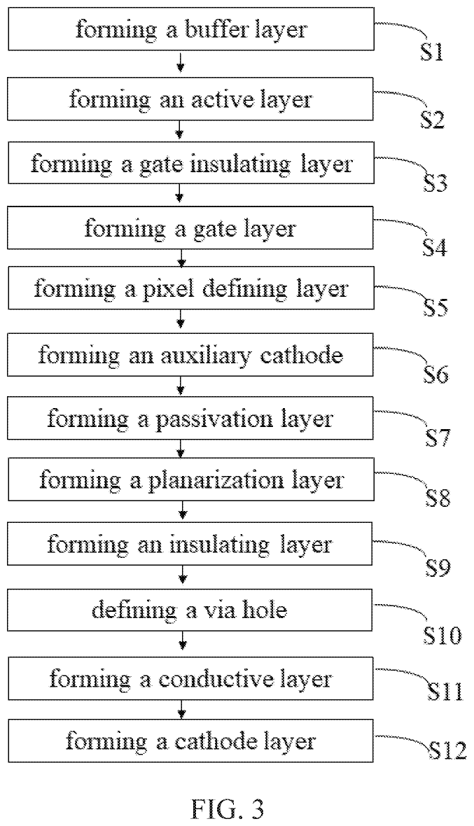

Referring to FIG. 3, a method of manufacturing a display panel includes steps S1 to S12.

In the step S1 of forming a buffer layer, a light shielding material is deposited on the upper surface of a substrate and is patterned to form a light shielding layer. An inorganic material is deposited on the upper surfaces of light shielding layer and the substrate. The inorganic material includes silicon oxide, silicon nitride, or a multilayer structure made of silicon oxide and silicon nitride, forms a buffer layer that has a buffer function.

In the step S2 of forming an active layer, a semiconductor material is deposited on the upper surface of the buffer layer. The semiconductor material includes indium gallium zinc oxide (IGZO), indium gallium titanium oxide (IZTO), indium gallium zinc oxide (IGZTO), etc. After performing patterning process, an active layer is formed, and the active layer is disposed opposite to the light shielding layer, and the active layer is used to provide circuit support for the display panel.

In the step S3 of forming a gate insulating layer, an inorganic material is deposited on the upper surface of the active layer. The inorganic material includes silicon oxide, silicon nitride, or a multilayer film structure. After performing the patterning process, a gate insulating layer is formed, and the gate insulating layer is disposed opposite to the active layer, and the gate insulating layer functions as an insulator to prevent short circuiting between traces in the display panel.

In the step S4 of forming a gate layer, a metal material is deposited on the upper surface of the gate insulating layer. The metal material includes molybdenum (Mo), aluminum (Al), copper (Cu), titanium (Ti), an alloy thereof, or a multilayer film structure. After performing the patterning process, a gate layer is formed, and the gate layer is disposed opposite to the gate insulating layer. In other embodiments, the semiconductor material, the inorganic material, and the metal material may be sequentially deposited, and it is finally patterned to form a gate layer, a gate insulating layer, and a semiconductor layer in order.

In the step S5 of forming an insulating layer, an inorganic material is deposited on the upper surfaces of the gate layer, the active layer, and the buffer layer. The inorganic material includes silicon oxide, silicon nitride, or a multilayer film structure, which functions as insulation to prevent short circuits. After performing the exposure and development processes by using a common mask, a via hole of insulating layer is defined on the insulating layer above the active layer, and the via hole of insulating layer penetrates through the insulating layer, and the via hole of insulating layer facilitates electrical connection between the electrode layer and the active layers.

In the step S6 of forming an auxiliary cathode, a metal material is deposited on the upper surface of the insulating layer by sputtering. The metal material includes molybdenum (Mo), aluminum (Al), copper (Cu), titanium (Ti), an alloy thereof, or a multilayer film structure. After performing the patterning process, a source/drain layer and an auxiliary cathode are formed. The source/drain layer is disposed opposite to the active layer, and a part of the metal material is disposed in the via hole of the insulating layer, and the source/drain layer is electrically connected to the active layer through the via hole of the insulating layer to form a circuit connection. The auxiliary cathode can be overlapped to the cathode to reduce the sheet resistance of the cathode.

In the step S7 of forming a passivation layer, a passivation layer is formed on the upper surfaces of the auxiliary cathode, the source/drain layer, and the insulating layer, and the material of the passivation layer includes silicon oxide, so the passivation layer has a blocking function and blocks external moisture.

In the step of S8 of forming a planarization layer, a planarization layer is formed on the upper surface of the passivation layer, and the planarization layer makes the surface of the film layer to be smooth, which facilitates the subsequent attaching of the film layer and avoids detachment. A via hole of the planarization layer is formed on the planarization layer after performing exposure and development by using a common mask, and the via hole of the planarization layer is disposed opposite to the source/drain layer to provide a channel for the electrode layer. An indium tin oxide material layer is deposited on the planarization layer to fill the via hole of the planarization layer, and an electrode layer is formed after patterning. The electrode layer is electrically connected to the source/drain layer, which provides circuit support for illumination of the subsequent luminescent material.

In the step S9 of forming a pixel defining layer, a pixel defining layer is formed on the upper surfaces of the electrode layer and the planarization layer to define a size of the light emitting layer.

In the step of S10 of defining a via hole, a via hole 14 (see FIG. 4) is defined after performing exposure and development by using a common mask, and the via hole 14 sequentially penetrates through the pixel defining layer 13, the planarization layer 11, and the passivation layer 10. The via hole 14 is disposed opposite to the auxiliary cathode 9 provide a channel for the conductive layer 17 and the cathode layer 18.

In the step of S11 of forming a conductive layer, the conductor layer 17 is formed in the via hole 14. The conductive layer 17 is made of nano silver and has good electrical conductivity. Referring to FIG. 5, a method of manufacturing the conductive layer includes steps of S111 to S114.

In the step of S111 of forming an organic layer, a second organic layer 151 is formed on an inner sidewall of the via hole 14 and a bottom thereof. The organic layer 15 is a multilayer film structure made of organic film layers. The organic layer 15 includes a hole injection layer, a hole transport layer, an electron injection layer, an electron transport layer, etc.

In the step of S112 of preparing a first reaction solution, an organic solvent (see FIG. 7) is printed in the via hole by an inkjet printing to cover the second organic layer 151 disposed above the auxiliary cathode 9, and then the second organic layer 151 is dissolved to form the first reaction solution 16.

In the step of S113 of preparing a second reaction solution, a nano silver solution is added above the first reaction solution by an inkjet printing, and then it is mixed with the first reaction solution to form a second reaction solution.

In the step of S114 of forming a conductive layer, the second reaction solution is vacuum-baked, and then the organic solvent is volatilized to precipitated nano silver, so a conductive layer 17 (see FIG. 8) is formed.

In the step of S12 of forming a cathode layer, the cathode layer 18 (see FIG. 2) is formed on the upper surfaces of the conductive layer 17 and the organic layer 15. The cathode layer 18 is effectively overlapped to the auxiliary cathode 9 through the conductive layer 17, which reduces the voltage drop of the display panel and further improves display uniformity of the display panel.

The technical effect of the method of manufacturing the display panel according to the embodiments of the present invention is that a conductive layer is formed in the via hole above the auxiliary cathode, and the conductive layer has a good conductivity, so that the cathode layer can be effectively overlapped to the auxiliary cathode and reduce the sheet resistance of the cathode layer. The voltage drop of the display panel is improved, and luminance uniformity in the display panel is further improved.

In the above, the present application has been described in the above preferred embodiments, but the preferred embodiments are not intended to limit the scope of the invention, and a person skilled in the art may make various modifications without departing from the spirit and scope of the application. The scope of the present application is determined by claims.

What is claimed is:

1. A display panel, comprising:
an insulating layer;
a passivation layer, wherein the passivation layer is disposed on a side surface of the insulating layer, and an auxiliary cathode is disposed in the passivation layer and attached to a surface of the insulating layer;
a planarization layer disposed on a side surface of the passivation layer away from the insulating layer;
a pixel defining layer disposed on a side surface of the planarization layer away from the passivation layer;
a via hole sequentially penetrating the pixel defining layer, the planarization layer, and the passivation layer, wherein the via hole is defined opposite to the auxiliary cathode; and
a conductive layer, wherein the conductive layer is disposed in the via hole and connected to the auxiliary cathode.

2. The display panel according to claim 1, further comprising:
an organic layer disposed on a side surface of the pixel defining layer away from the planarization layer; and
a cathode layer disposed on a side surface of the conductive layer and the organic layer away from the pixel defining layer.

3. The display panel according to claim 1, wherein a thickness of the conductive layer is less than a depth of the via hole.

4. The display panel according to claim 1, wherein the conductor layer is made of nano silver.

5. The display panel according to claim 2, wherein the cathode layer is electrically connected to the conductive layer, and the conductive layer is electrically connected to the auxiliary cathode.

6. The display panel according to claim 1, further comprising:
a substrate;
a buffer layer disposed on a side surface of the substrate;
an active layer disposed on a side surface of the buffer layer away from the substrate;
a gate insulating layer disposed on a side surface of the active layer away from the buffer layer;
a gate layer disposed on the side surface of the gate insulating layer away from the active layer; and
a source/drain layer disposed on the side surface of the insulating layer away from the buffer layer, wherein the source/drain layer is passed through the insulating layer and electrically connected to the active layer.

7. A method of manufacturing a display panel, comprising following steps of:
forming an insulating layer, wherein the insulating layer is formed on an upper surface of a substrate;
forming an auxiliary cathode, wherein the auxiliary cathode is formed on an upper surface of the insulating layer;
forming a passivation layer, wherein the passivation layer is formed on the upper surface of the insulating layer and an upper surface of the auxiliary cathode;
forming a planarization layer, wherein the planarization layer is formed on an upper surface of the passivation layer;
forming a pixel defining layer, wherein the pixel defining layer is formed on an upper surface of the planarization layer;
defining a via hole, wherein the via hole is sequentially penetrating the pixel defining layer, the planarization layer, and the passivation layer; and the pixel defining layer, the planarization layer, and the passivation layer are disposed above the auxiliary cathode; and
forming a conductive layer, wherein the conductive layer is formed in the via hole.

8. The method of manufacturing a display panel according to claim 7, wherein a step of the forming the conductive layer comprises following steps of:
forming an organic layer, wherein the organic layer is formed on an upper surface of the pixel defining layer, and a second organic layer is formed on an inner sidewall of the via hole and a bottom thereof;
preparing a first reaction solution, wherein an organic solvent is added to the via hole, and the second organic layer is dissolved to form the first reaction solution;
preparing a second reaction solution, wherein a nano silver solution is added to the via hole, and the nano silver solution is mixed with the first reaction solution to form the second reaction solution; and
forming the conductive layer, wherein the second reaction solution is processed to form the conductive layer.

9. The method of manufacturing a display panel according to claim 8, after a step of forming the conductive layer, wherein the step of forming the conductive layer further comprises following steps:
forming the cathode layer, and the cathode layer is formed on an upper surface of the organic layer and an upper surface of the conductive layer.

10. The method of manufacturing a display panel according to claim 8, wherein a step of the forming the conductive layer comprises following steps:
vacuum baking the second reaction solution; and
volatilizing the organic solvent to precipitate nano silver.
